(19) United States
(12) Patent Application Publication
(10) Pub. No.: US 2020/0373195 A1
(43) Pub. Date: Nov. 26, 2020

(54) PROCESSING CHAMBER FOR THERMAL PROCESSES

(71) Applicant: Applied Materials, Inc., Santa Clara, CA (US)

(72) Inventors: Shu-Kwan Lau, Sunnyvale, CA (US); Zhiyuan Ye, San Jose, CA (US); Martin A. Hilkene, Gilroy, CA (US)

(21) Appl. No.: 16/854,295

(22) Filed: Apr. 21, 2020

Related U.S. Application Data
(60) Provisional application No. 62/850,196, filed on May 20, 2019.

(51) Int. Cl. H01L 21/687; H01L 21/67

(52) U.S. Cl. CPC H01L 21/68764; H01L 21/67248; H01L 21/67155

(57) ABSTRACT

Embodiments of the disclosure include methods and apparatus for a thermal chamber with a low thermal mass. In one embodiment, a chamber is disclosed that includes a body, a susceptor positioned within the body, a first set of heating devices positioned in an upper portion of the body above the susceptor and a second set of heating devices positioned in a lower portion of the body below the susceptor, wherein each of the first set of heating devices have a heating element having a longitudinal axis extending in a first direction, and each of the second set of heating devices have a heating element having a longitudinal axis extending in a second direction that is orthogonal to the first direction, and wherein each of the heating elements have ends that are exposed to ambient environment.

### CROSS-REFERENCE TO RELATED APPLICATION

This application claims priority to U.S. provisional patent application Ser. No. 62/850,196, filed May 20, 2019, which is hereby incorporated by reference herein.

### BACKGROUND

### Field

Embodiments of the disclosure relate to methods and apparatus for temperature control of a thermal processing chamber.

### Description of the Related Art

In semiconductor fabrication processes, a semiconductor substrate is heated during various thermal processes, for example, during film deposition, film growth, and/or etching. When heating the substrate, uniformity of temperature of the substrate provides uniform processing on the substrate. For instance in film deposition, if the temperature in one region of the substrate varies from another region, the thickness of the deposition in these regions may not be the same. Additionally, the adhesion of the films on the substrate may vary as well. Furthermore, if the temperature in one region of the substrate is higher or lower than the temperature in another region of the substrate, a temperature gradient within the substrate material is formed. This temperature gradient produces thermal moments in the substrate, which in turn induces local thermal stresses in the substrate. These local thermal stresses can reduce the substrate's strength and, furthermore, damage the substrate.

What is needed is processing chamber that enables more efficient thermal control.

### SUMMARY

Embodiments of the disclosure include methods and apparatus for a thermal chamber with a low thermal mass. In one embodiment, a chamber is disclosed that includes a body, a susceptor positioned within the body, a first set of heating devices positioned in an upper portion of the body above the susceptor and a second set of heating devices positioned in a lower portion of the body below the susceptor, wherein each of the first set of heating devices have a heating element having a longitudinal axis extending in a first direction, and each of the second set of heating devices have a heating element having a longitudinal axis extending in a second direction that is orthogonal to the first direction, and wherein each of the heating elements have ends that are exposed to ambient environment.

In another embodiment, a chamber is disclosed that includes a body, a susceptor positioned within the body, a first set of heating devices positioned in an upper portion of the body above the susceptor and a second set of heating devices positioned in a lower portion of the body below the susceptor, and a boundary plate positioned between the susceptor and the second set of heating devices, wherein each of the first set of heating devices have a heating element having a longitudinal axis extending in a first direction, and each of the second set of heating devices have a heating element having a longitudinal axis extending in a second direction that is orthogonal to the first direction, and wherein each of the heating elements are disposed in an optically transparent tube that extends outside of the body.

In another embodiment, a chamber is disclosed that includes a body, a susceptor positioned within the body, a first set of heating devices positioned in an upper portion of the body above the susceptor and a second set of heating devices positioned in a lower portion of the body below the susceptor, wherein each of the first set of heating devices have a heating element having a longitudinal axis extending in a first direction, and each of the second set of heating devices have a heating element having a longitudinal axis extending in a second direction that is different than the first direction, and wherein each of the heating elements are disposed in an optically transparent tube that extends outside of the body.

### BRIEF DESCRIPTION OF THE DRAWINGS

So that the manner in which the above recited features can be understood in detail, a more particular description of embodiments of the disclosure, briefly summarized above, may be had by reference to the embodiments, some of which are illustrated in the appended drawings. It is to be noted, however, that the appended drawings illustrate only typical embodiments and are therefore not to be considered limiting of its scope, for the disclosure may admit to other equally effective embodiments.

FIG. 1A is a schematic isometric view of one embodiment of a processing chamber.

FIG. 1B is a sectional view of the processing chamber along lines 1B-1B of FIG. 1A.

FIG. 1C is a bottom view of the processing chamber of FIGS. 1A and 1B showing portions thereof in cross-section.

FIG. 1D is a top view of the processing chamber of FIGS. 1A-1C showing portions thereof in cross-section.

FIG. 2 is a schematic side view of a portion of the processing chamber showing the heating devices protruding from a face of the sidewall.

FIGS. 3A and 3B are schematic sectional views of one embodiment of an internal reflector that may be utilized in the tubes of the heating devices.

FIGS. 4A and 4B are schematic sectional views of one embodiment of a lower liner that may be utilized in the processing chamber of FIGS. 1A and 1B.

FIG. 5 is a schematic sectional view of a tube having a reflective coating formed thereon.

FIG. 6 is a schematic sectional view of another embodiment of a processing chamber.

FIG. 7A is a schematic sectional view of another embodiment of a processing chamber.

FIG. 7B is a top plan view of a portion of the processing chamber of FIG. 7A.

FIGS. 8A-8C are schematic side views of an actuator system for rotating the internal reflectors of the heating elements.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the disclosure relate to methods and apparatus for a processing chamber for thermal treatment of substrates utilized in electronic device manufacture. Certain embodiments disclosed include thermal processes on substrates such as epitaxial deposition processes, rapid thermal processing (e.g., anneal processes), etch process, and the like.

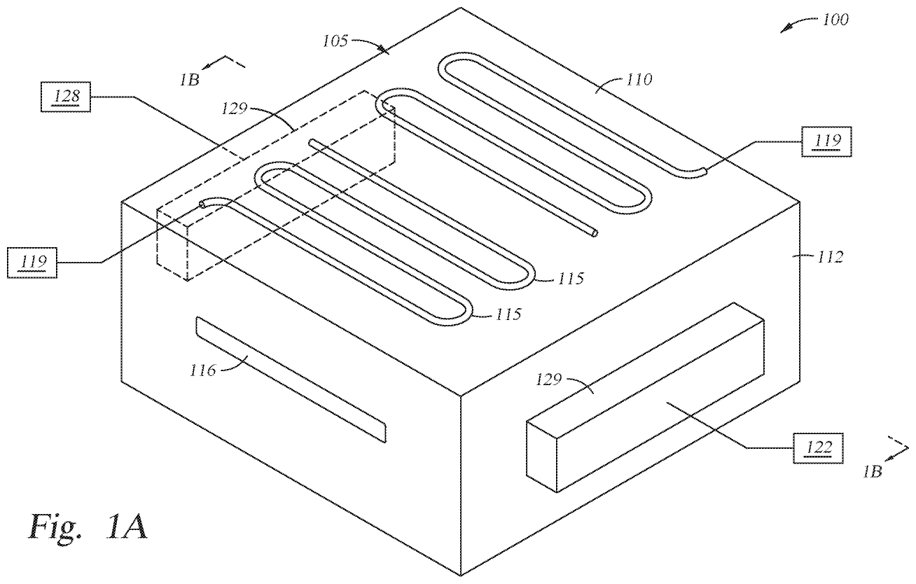

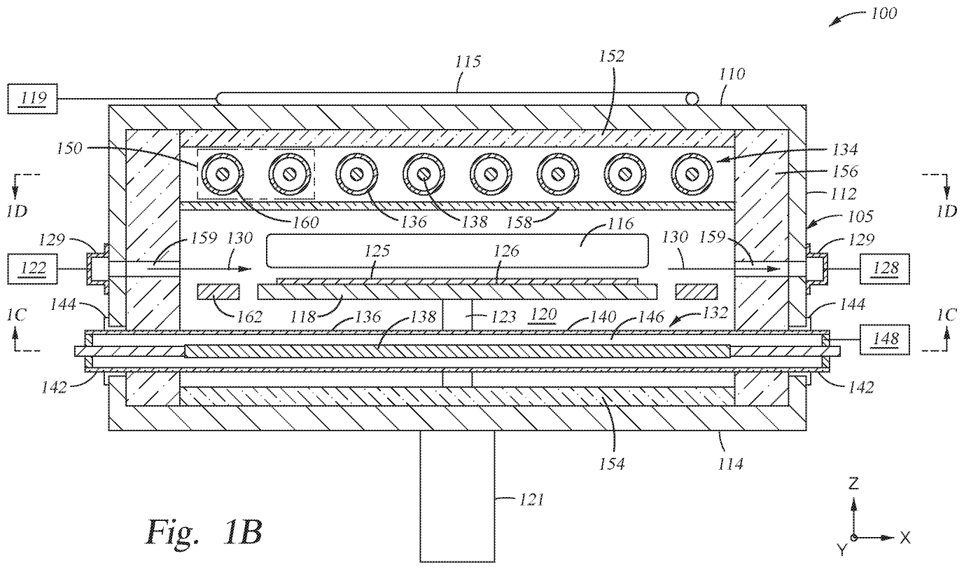

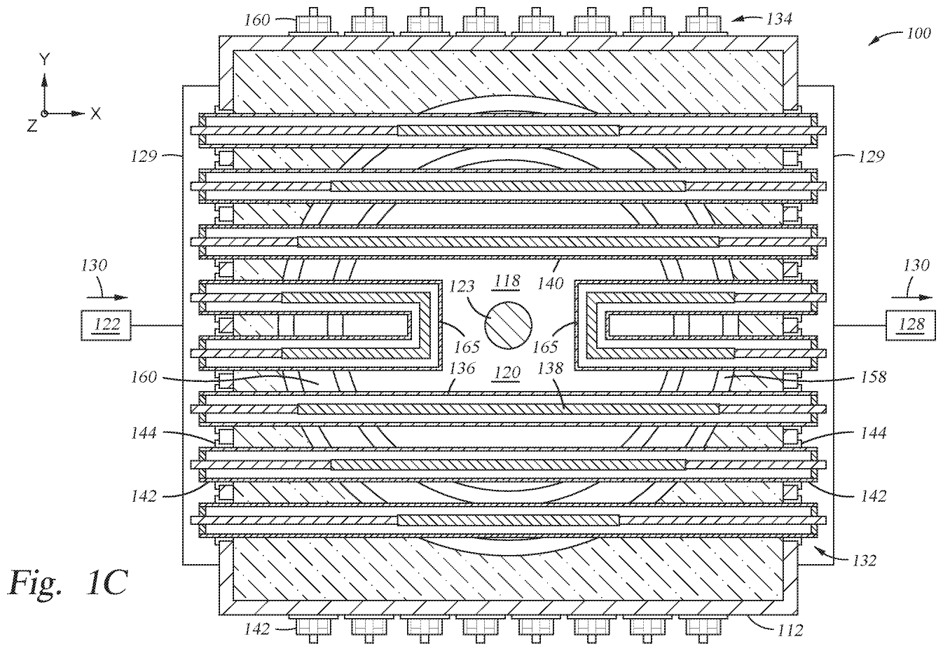

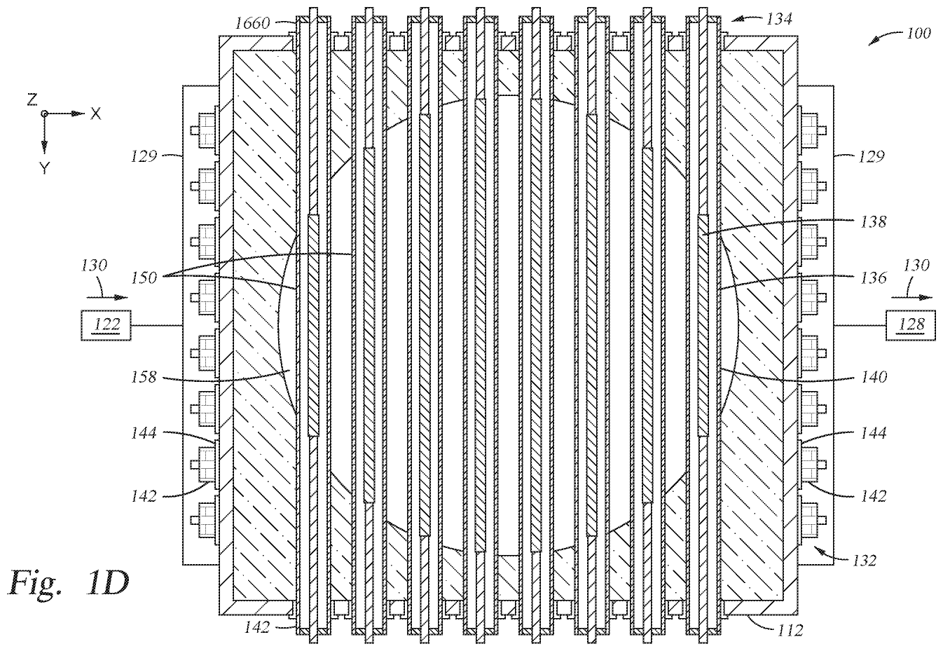

FIGS. 1A-1D are schematic views of a processing chamber 100. FIG. 1A is a schematic isometric view of the processing chamber 100. FIG. 1B is a sectional view of the processing chamber 100 along lines 1B-1B of FIG. 1A. FIG. 1C is a bottom view of the processing chamber 100 of FIGS. 1A and 1B showing portions thereof in cross-section. FIG. 1D is a top view of the processing chamber 100 of FIGS. 1A-1C showing portions thereof in cross-section.

The processing chamber 100 includes a body 105. The body 105 includes a top 110, sidewalls 112 and a bottom 114 (shown in FIG. 1B). The body 105 may be made of a metallic material, such as material that resists corrosive chemistries and/or high temperatures, for example, stainless steel or aluminum. The processing chamber 100 also includes a substrate transfer port 116 (shown in FIG. 1A). The transfer port 116 is utilized for transferring substrates to and from a susceptor 118 (shown in FIG. 1B). The susceptor is disposed in a process volume 120 (shown in FIGS. 1B-1D) defined by the body 105. Thermal control channels 115 may be formed in or on the body 105. The thermal control channels 115 are coupled to a coolant source 119 that dynamically cools the processing chamber 100.

The processing chamber 100 is coupled to a gas injection source 122 disposed on one side of the body 105. Process gases are injected into the process volume 120 and flow across a substrate 125 (shown in FIG. 1B) positioned on a substrate receiving surface 126 of the susceptor 118 to an exhaust port 128. The exhaust port 128 is provided on the processing chamber 100 in a position opposing the gas injection source 122. As such, process gases flow in a substantially straight flow path 130 from the gas injection source 122 to the exhaust port 128. Unused process gases are then pumped out of the processing chamber 100 through the exhaust port 128. The exhaust port 128 may also be utilized to vary pressure in the process volume 120, such as a pressure below atmospheric or ambient pressure. Alternatively, a vacuum pump may be operably coupled to the process volume 120 to provide negative pressures therein. Each of the gas injection source 122 and the exhaust port 128 are coupled to a manifold 129. The manifold 129 on the gas injection source 122 side is an inject manifold that spreads process gases from the gas injection source 122. The manifold 129 on the exhaust port 128 side is an exhaust manifold that exhausts gases from the processing chamber 100. Both of the manifolds 129 extend a length or width of the body 105. Thus, the manifolds 129 provide uniform flow across a diameter of the substrate 125. In some implementations, the susceptor 118 is coupled to a rotary actuator 121 by a shaft 123 that extends into the process volume 120. The rotary actuator 121 may be adapted to move the susceptor 118 vertically (in the Z direction) within the process volume 120 as well as rotate. In other implementations, the susceptor 118 is coupled to a levitation device (not shown), such as a magnetic stator/rotor assembly that is adapted to rotate as well as move vertically within the process volume 120.

The following description is based primarily on FIG. 1B although some components described herein may be present in other Figures.

The process volume 120 is heated by a first set of heating devices 132 and a second set of heating devices 134. The first set of heating devices 132 are provided below the susceptor 118 and are utilized to heat the susceptor 118 and/or the substrate 125. The second set of heating devices 134 are positioned above the susceptor 118. The second set of heating devices 134 are utilized to heat one or a combination of the process gases, the substrate 125 and the susceptor 118.

The first set of heating devices 132 and the second set of heating devices 134 include tubes 136 having a heating element 138 provided therein. Each of the tubes 136 have a first portion 140 that is within the process volume 120 and ends (e.g., a second portion) 142 that are outside of the process volume 120 (i.e., outside of the processing chamber 100). Each of the heating elements 138 may be one or a combination of lamps and a metallic heating device embedded in a ceramic material, such as silicon carbide (SiC). Seals 144 are provided between the ends 142 and the sidewalls 112 in order to hermetically seal the process volume 120 at locations where the tubes 136 protrude outside of the processing chamber 100. Thus, an interior 146 of each of the tubes 136 are in ambient pressure(s) while the process volume 120 may be at a pressure below ambient pressure. Additionally, the heating elements 138, positioned in the interior 146, are protected from pressures and/or chemistries in the processing chamber 100. Each of the tubes 136 are made from an optically transparent material, in some implementations. In one example, each of the tubes 136 is made of clear (e.g., optically transparent to one or more wavelengths of light, such as light in the visible spectrum) quartz.

As the tubes 136 protrude outside of the body 105 of the processing chamber 100, and the interior 146 of the tubes 136 have a space between the heating elements 138 and the wall of the tubes 136, a cooling fluid from a cooling source 148 may be provided thereto. For example, a fluid such as clean dry air, nitrogen, or other gas may be flowed through the tubes 136 to cool the tubes 136. Thus, the first set of heating devices 132 and the second set of heating devices 134 may be utilized to rapidly heat the susceptor 118 and/or the substrate 125, and cooled rapidly using the cooling source 148. Therefore, the processing chamber 100 as described herein provides fast ramp-up and cool down which enables enhanced temperature control of the substrate 125. Thus, the processing chamber 100 as described herein provides more efficient heating and cooling of the substrate 125.

Power to each of the heating elements 138 may be individually controlled, or in groups. For example, temperatures provided by each of the heating elements 138 may be controlled individually or a group 150 of two more heating elements 138 may be controlled simultaneously.

The processing chamber 100 includes one or more liners, shown as an upper liner 152, a lower liner 154, and a sidewall liner 156. In some implementations, the upper liner 152 and the lower liner 154 comprise a reflective material, such as a reflective quartz material, a reflective coating, or other reflective material. One or both of the upper liner 152 and the lower liner 154 comprises an emissivity of about 0.6 to about 0.2, or less, such as about 0.01.

The upper liner 152 and the lower liner 154 are utilized to reflect thermal energy from the heating elements 138 back toward the substrate 125 and/or the susceptor 118. For example, any thermal energy from the first set of heating devices 132 not reaching the susceptor 118 is redirected towards the susceptor 118 by the lower liner 154. Likewise, any thermal energy from the second set of heating devices 134 not reaching the substrate 125 is redirected back toward the substrate 125. The sidewall liner 156 is an opaque material, such as opaque quartz, or other opaque material or coating. Openings 159 are formed in the sidewall liner 156 to provide fluid communication between the process volume 120, and the gas injection source 122 and the exhaust port 128. The upper liner 152, the lower liner 154 and the sidewall liner 156 efficiently thermally insulates the process volume 120 and/or prevents heat loss. The reflectivity of the upper liner 152 and the lower liner 154 provides a low thermal mass. The liners also envelopes the process volume 120 for chemical protection of other components of the processing chamber 100.

During operation, the heating elements 138 heat the susceptor 118 by direct (line of sight) radiation and reflected radiation (from the upper liner 152 and the lower liner 154). By providing the heating elements 138 inside the process volume 120 in proximity to the susceptor 118 space between the heating elements 138 and the susceptor 118 is reduced, which minimizes heat loss paths as well as maximizes heating efficiency.

In some implementations, the processing chamber 100 includes a boundary plate 158. The boundary plate 158 is positioned between the second set of heating devices 134 and the susceptor 118. The boundary plate 158 is a plate made of an optically transparent material, such as quartz, that is substantially transparent to thermal energy from the heating elements 138. The boundary plate 158 may be thin in cross-section as the boundary plate 158 is positioned within the process volume 120 (subject to the same pressure on both sides thereof). Therefore, forces, such as pressure, are substantially equal on both major surfaces of the boundary plate 158. This is differentiated from conventional thermal chambers that may include a plate or member that contains vacuum pressures on one side from ambient pressures on the other side, which typically requires one or both of a thicker cross-section and bends formed therein that increase the physical strength thereof. Thus, the processing chamber 100 is more compact which enables more efficient thermal control.

In FIG. 1B, based on a longitudinal direction of each of the tubes 136 and/or the heating elements 138, the first set of heating devices 132 is shown positioned in a first direction and the second set of heating devices 134 is shown positioned in a second direction that is different than the first direction. The first direction is substantially (e.g., within less than about 5 degrees) orthogonal to the second direction. The first direction of the first set of heating devices 132 is substantially orthogonal to the flow path 130. The second direction is generally parallel to the flow path 130.

In operation, process gases are provided from the gas injection source 122 and flows across the substrate 125 towards the exhaust port 128. Both of the first set of heating devices 132 and the second set of heating devices 134 are then controlled to heat the substrate 125 and/or the susceptor 118 to a desired temperature. However, gases entering the process volume 120 adjacent to the gas injection source 122 may be preheated using energy from a first heating device 160 (e.g., an upstream heating element) and/or the group 150 of the second set of heating devices 134. Additionally, a pre-heat ring 162 may be utilized outside of the periphery of the susceptor 118 to preheat the gases prior to residence over the substrate 125. For example, heating elements 138 in the first heating device 160 and/or the group 150 may be controlled to provide a temperature greater than a temperature of the remainder of the heating elements 138. The increased temperature at the upstream portion of the flow path 130 heats one or both of the pre-heat ring 162 and the gases to a temperature that facilitates disassociation of the gases in a portion of the flow path 130 prior reaching the portion of the flow path 130 over the substrate 125. A temperature of the remainder of the heating elements 138 is then provided to maintain disassociation of the gases across the remainder of the flow path 130. After a film formation process or an etch process using the processing chamber 100, the first set of heating devices 132 and the second set of heating devices 134 may be actively cooled using the cooling source 148.

FIG. 1C is a schematic bottom view of the processing chamber 100 with the bottom 114 and the lower liner 154 removed to show the first set of heating devices 132 and the susceptor 118. FIG. 1D is a schematic top view of the processing chamber 100 with the top 110 and the upper liner 152 removed to show the second set of heating devices 134 and the susceptor 118.

In the embodiment shown in FIG. 1C, a center set of heating devices 165 are U-shaped. The U shape of the center set of heating devices 165 are utilized to provide space for the shaft 123 when a shaft is used. In some implementations, a levitating susceptor is utilized such that no stem, or no center set of heating devices 165 having the U shape are needed. In other implementations, the center set of heating devices 165 are not used when temperature control is provided efficiently from other heating elements 138 of the first set of heating devices 132.

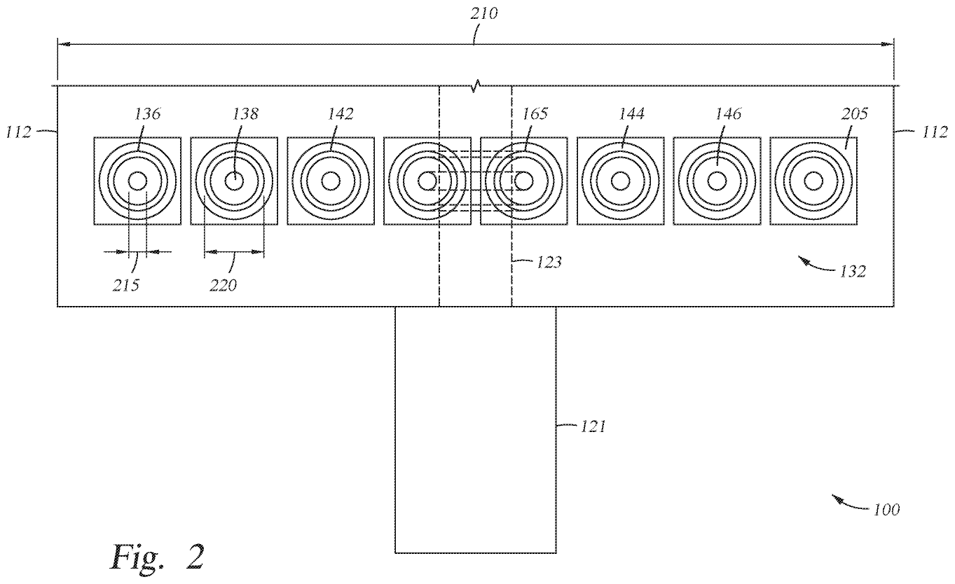

FIG. 2 is a schematic side view of a portion of the processing chamber 100 showing the first set of heating devices 132 protruding from a face 200 of the sidewall 112. One or more caps 205 are provided on the face 200. Each of the caps 205 are made of a material that resists corrosive chemistries and/or high temperatures, for example, stainless steel or aluminum. Each of the caps 205 are fastened to the face 200, such as by bolts or screws (not shown). Each of the tubes 136 are fixed to the cap 205 by a seal 144. While not shown, the sidewall 112 opposing the face 200 may be configured similarly. Additionally, the second set of heating devices 134 may be fixed to the body 105 of the processing chamber 100 as the first set of heating devices 132 are described.

While six heating elements 138 in the respective tubes 136 are shown, any number of heating element 138 and tubes 136 may be utilized. A distance 210 between the sidewalls 112 may be about 400 millimeters (mm). As such, the first set of heating devices 132 has a collective width sufficient to provide thermal energy to a 300 mm substrate. A width 215 of the heating elements 138 is about 8 mm to about 12 mm. While not shown, a length of the heating element 138 is greater than a diameter of a 300 mm substrate. A width 220 of each tube 136 is about 33 mm to about 37 mm, and a length (not shown) of the tubes 136 may be up to about 600 mm.

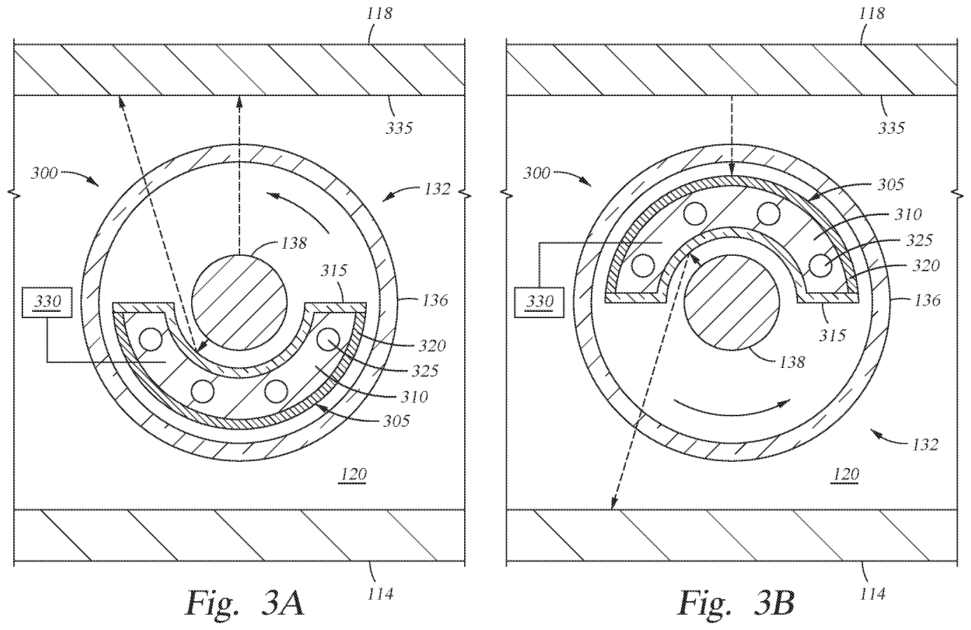

FIGS. 3A and 3B are schematic sectional views of one embodiment of an internal reflector 300 that may be utilized in the tubes 136 of the first set of heating devices 132. While not shown, the tubes 136 of the second set of heating devices 134 may be configured similarly. FIG. 3A shows a position of the internal reflector 300 during a temperature ramp-up procedure and FIG. 3B shows a position of the internal reflector 300 during a cool down procedure. The internal reflector 300 includes a length that is substantially the same as the heating element 138.

The internal reflector 300 includes a rotatable structure 305. The rotatable structure 305 rotates about an axis that is generally a center of a longitudinal axis of the heating element 138. The rotatable structure 305 includes an arcuate member 310 having one or more coatings formed thereon. A first coating 315 is formed generally on an inside diameter of the arcuate member 310. A second coating 320 is formed generally on an outside diameter of the arcuate member 310. The first coating 315 is a generally reflective material while the second coating 320 is generally a material resembling a black body (e.g., an emissivity value of near 1).

The arcuate member 310 may be formed from a metallic material, such as stainless steel or copper. The first coating 315 is a reflective material, such as silver (Ag) or gold (Au). As described above, the second coating 320 is a black material configured to absorb heat and/or light similar to a black body. It is to be noted that a black material as used herein may include dark colors, such as the color black, but is not limited to dark colored materials or coatings. More generally, a black material, a black finish, or a black coating refers to the lack of reflectivity or the ability the material, finish, or coating to absorb energy, such as heat and/or light, similar to a black body.

The internal reflector 300 includes one or more thermal control channels 325 formed therein. For example, the one or more thermal control channels 325 are formed in the arcuate member 310 along a length thereof. Each of the one or more thermal control channels 325 may be a heat pipe or a cooling channel. In some implementations, the one or more thermal control channels 325 are coupled to the cooling source 148 (shown in FIG. 1B).

The internal reflector 300 is coupled to an actuator 330. The actuator 330 is utilized to rotate the internal reflector 300 from the position shown in FIG. 3A to the position shown in FIG. 3B.

In operation, the internal reflector 300 directs thermal energy from the heating element 138 toward a backside 335 of the susceptor 118 during a temperature ramp-up process. Additionally, during a temperature ramp-up process, the internal reflector 300 redirects thermal energy from the heating element 138 toward the backside 335 of the susceptor 118 that is reflected using the first coating 315.

During a cool down process as shown in FIG. 3B, the internal reflector 300 is rotated about 180 degrees from the position shown in FIG. 3A. While the heating element 138 may be powered down after the temperature ramp-up process shown in FIG. 3A, some thermal energy may remain in and/or be emitted from the heating element 138. Thus, any remaining thermal energy from the heating element 138 is directed and/or redirected toward the bottom 114. In this embodiment, the lower liner 154 (shown in FIG. 1B) is not utilized, and a surface of the bottom 114 absorbs any direct or reflected thermal energy from the heating element 138. Additionally, a portion of the thermal energy radiating from the susceptor 118 is absorbed by the second coating 320. The thermal energy absorbed by the second coating 320 may be dissipated and/or removed by the one or more thermal control channels 325 of the internal reflector 300. Thus, the susceptor 118, and the substrate thereon (not shown) is cooled quickly.

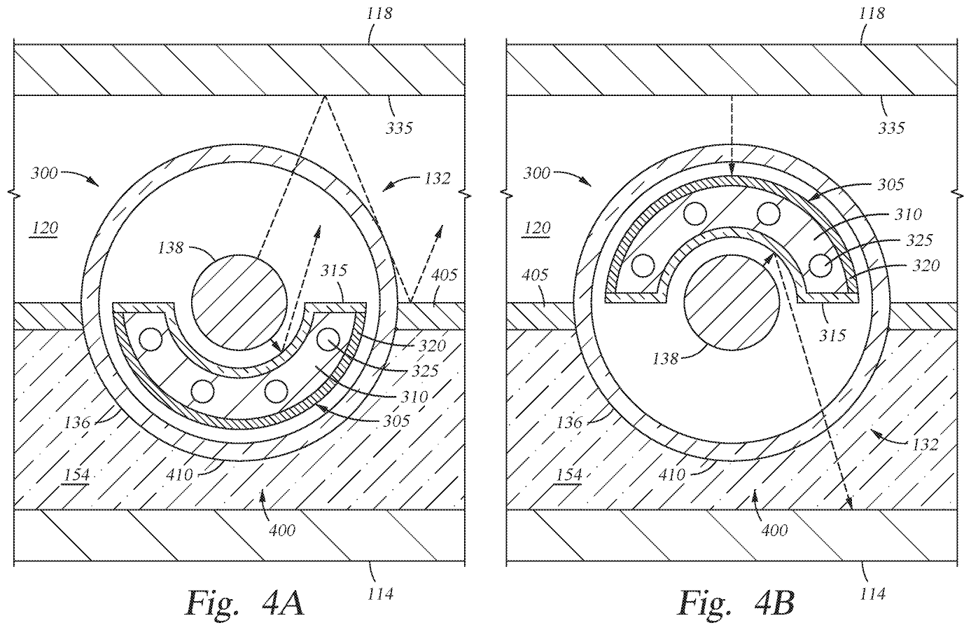

FIGS. 4A and 4B are schematic sectional views of one embodiment of the lower liner 154 that may be utilized in the processing chamber 100 of FIGS. 1A and 1B. FIGS. 4A and 4B show tubes 136 of the first set of heating devices 132. While not shown, the tubes 136 of the second set of heating devices 134 may be configured similarly. Similar to FIGS. 3A and 3B, FIG. 4A shows a position of the internal reflector 300 during a temperature ramp-up procedure and FIG. 4B shows a position of the internal reflector 300 during a cool down procedure. While not specifically described in FIGS. 4A and 4B, the internal reflector 300 is similar to, and operates similarly as, the internal reflector 300 of FIGS. 3A and 3B.

The lower liner 154 according to this embodiment includes a first thermal insulator 400 and a second thermal insulator 405. The first thermal insulator 400 includes a trench 410 where a portion of the tube 136 is positioned. The second thermal insulator 405 is in the form of discrete tiles that are positioned between adjacent tubes 136 and on the upper surface of the first thermal insulator 400.

The first thermal insulator 400 is a semi-opaque quartz material configured to absorb portions of thermal energy, and allow other portions of thermal energy to pass through to the bottom 114. The bottom 114 is configured to absorb any thermal energy passing through the first thermal insulator 400. The second thermal insulator 405 is a reflective material, such as a reflective quartz material, that blocks thermal energy from the process volume 120 from entering the first thermal insulator 400 (at positions where the second thermal insulator 405 is located relative to the process volume 120).

In operation, the internal reflector 300 directs thermal energy from the heating element 138 toward the backside 335 of the susceptor 118 during a temperature ramp-up process, as shown in FIG. 4A. Additionally, during a temperature ramp-up process, the internal reflector 300 redirects thermal energy from the heating element 138 toward the backside 335 of the susceptor 118 that is reflected using the first coating 315.

During a cool down process as shown in FIG. 4B, the internal reflector 300 is rotated about 180 degrees from the position shown in FIG. 4A. While the heating element 138 may be powered down after the temperature ramp-up process shown in FIG. 4A, some thermal energy may remain in and/or be emitted from the heating element 138. Thus, any remaining thermal energy from the heating element 138 is directed and/or redirected through the first thermal insulator 400 toward the bottom 114. The bottom 114 absorbs any direct or reflected thermal energy from the heating element 138. Additionally, a portion of the thermal energy radiating from the susceptor 118 is absorbed by the second coating 320. The thermal energy absorbed by the second coating 320 may be dissipated and/or removed by the one or more thermal control channels 325 of the internal reflector 300. Thus, the susceptor 118, and the substrate thereon (not shown) is cooled quickly.

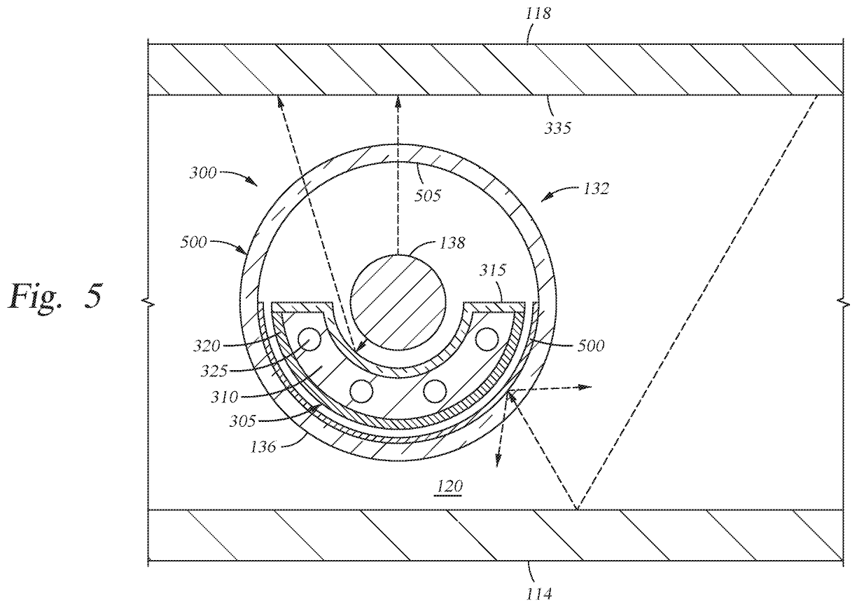

FIG. 5 is a schematic sectional view of a tube 136 having a reflective coating 500 formed thereon. FIG. 5 shows a tube 136 of one of the tubes 136 of the first set of heating devices 132. While not shown, the tubes 136 of the second set of heating devices 134 may be configured similarly.

The tube 136 includes the internal reflector 300 as described in FIGS. 3A and 3B above, and also includes the internal reflector 300. The reflective coating 500 comprises a film or coating disposed on a portion of an inside diameter 505 of the tube 136. For example, the reflective coating 500 is a semicircular coating or film disposed on about one-half of the inside diameter 505 of the tube 136.

In operation, thermal energy emanating from the backside 335 of the susceptor 118 is directed toward the bottom 114. In some embodiments, the lower liner 154 (shown in FIG. 1B) is not utilized, and a surface of the bottom 114 absorbs thermal energy reflected from the backside 335 of the susceptor 118. Any thermal energy that is not absorbed by the bottom 114 is reflected through the tube 136 to the reflective coating 500. The reflective coating 500 then re-reflects this thermal energy back toward the bottom 114.

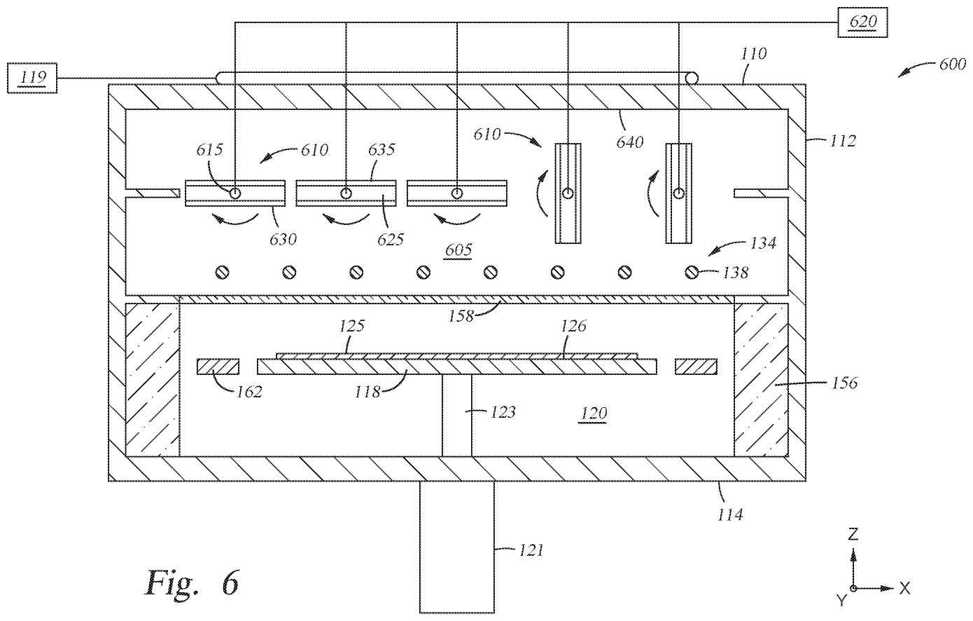

FIG. 6 is a schematic sectional view of another embodiment of a processing chamber 600. The processing chamber 600 is similar to the processing chamber 100 shown and described in FIGS. 1A and 1B with the following exceptions.

The processing chamber 600 includes the second set of heating devices 134 disposed in an upper volume 605 that is sealed from the process volume 120. While not shown, other components of the processing chamber 600 are similar to the processing chamber 100 shown and described in FIGS. 1A and 1B.

The main differences are that the heating elements 138 are not in tubes as described in other Figures, but are within the upper volume 605. The upper volume 605 is bounded by the top 110, a portion of the sidewalls 112, and the boundary plate 158. The boundary plate 158 is an optically transparent material as described above. The upper volume 605 is maintained at a pressure that is different than the pressure of the process volume 120. For example, the upper volume 605 is maintained at a pressure at or near ambient or atmospheric pressure.

Additionally, the second set of heating devices 134 includes a plurality of shutters 610. Each of the shutters 610 are configured to rotate about an axis of a shaft 615 in order to reflect thermal energy from the heating elements 138, or let thermal energy pass thereby. Additionally, while not shown, the first set of heating devices 132 may be disposed in a lower volume of the processing chamber 600, and the first set of heating devices 132 are configured similar to the second set of heating devices 134 (having heating elements and shutters within a boundary plate disposed between the bottom 114 and the susceptor 118).

Each of the shutters 610 includes the shaft 615. As in other embodiments, the shafts 615 extend outside of the sidewalls 112 of the processing chamber 600. Each of the shafts 615 are coupled to an actuator 620 that moves the shutters 610 in the rotational axis. The actuator 620 is positioned outside of the sidewalls 112 of the processing chamber 600.

Each of the shutters 610 includes a body 625. The body 625 is generally rectangular in cross-section. The body 625 includes a first coating 630 and a second coating 635. The first coating 630 is formed on one major surface of the body 625 and the second coating 635 is formed on the body 625 on an opposing major surface. The first coating 630 is a generally reflective material while the second coating 635 is generally a material resembling a black body. The first coating 630 is a reflective material, such as silver (Ag) or gold (Au). As described above, the second coating 635 is a black material configured to absorb heat and/or light similar to a black body.

In a temperature ramp-up process using the shutters 610, the shutters 610 are positioned as shown on the left side of FIG. 6. The shutters 610 are positioned such that a plane of a major surface of the shutters 610 is substantially parallel to a plane of a major surface of the boundary plate 158. Thermal energy from the heating elements 138 is provided either directly or indirectly to the substrate 125 and/or the susceptor 118. For example, some of the thermal energy is provided directly from the heating elements 138 to the substrate 125 and/or the susceptor 118. Other portions of the thermal energy from the heating elements 138 is reflected by the first coating 630 and redirected back toward the substrate 125 and/or the susceptor 118.

In a cool down process, as shown on the right side of FIG. 6, the shutters 610 are rotated about 180 degrees form the position shown on the left side of FIG. 6. A minor surface of the shutters 610 is substantially parallel to the major surface of the boundary plate 158. In this position, a portion of the thermal energy retained in the substrate 125 and/or the susceptor 118 is directed toward the top 110 of the processing chamber 600. The top 110 is configured to absorb the thermal energy directed past the shutters 610. In some embodiments, an interior surface of the top 110 includes a coating 640 configured to absorb thermal energy. The coating 640 is a black material configured to absorb heat and/or light similar to a black body. In some implementations, the top 110 is coupled to the coolant source 119 that dynamically cools the processing chamber 100.

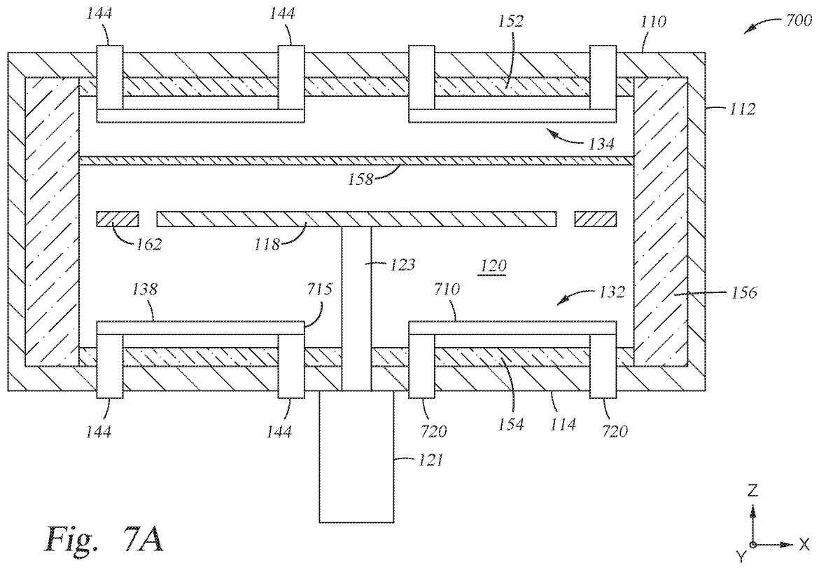

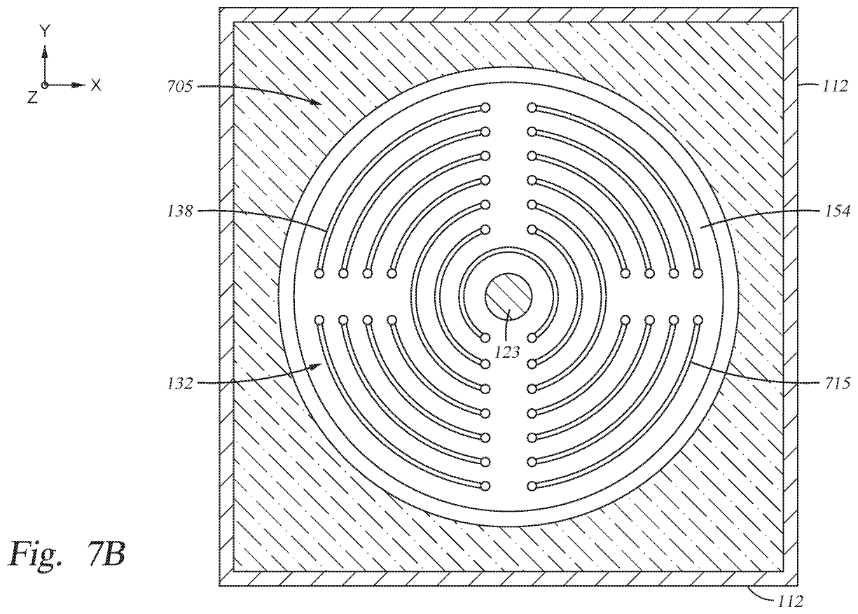

FIGS. 7A and 7B are various views of another embodiment of a processing chamber 700. FIG. 7A is a schematic sectional view of the processing chamber 700. The processing chamber 700 includes the top 110, the sidewalls 112 and the bottom 114 similar to other processing chambers as disclosed herein. The processing chamber 700 also includes features such as the susceptor 118 and the boundary plate 158 as well as other portions that will not be listed for brevity. FIG. 7B is a top plan view of a portion of the processing chamber 700 below the susceptor 118 (not shown in FIG. 7B).

The processing chamber 700 includes the first set of heating devices 132 and the second set of heating devices 134 as disclosed in other embodiments. However, the first set of heating devices 132 and the second set of heating devices 134 include a plurality of heating elements 138 comprising an arcuate array 705 (shown in FIG. 7B).

In this embodiment, each of the heating elements 138 may be one or a combination of lamps and a metallic heating device embedded in a ceramic material, such as SiC. In the case where lamps are utilized, a tube 710 made of an optically transparent material, such as quartz, surround the lamps.

Seals 144 are provided adjacent to the ends 142 of the heating elements 138 and the sidewalls 112 in order to hermetically seal the process volume 120 at locations where electrical leads 720 protrude outside of the processing chamber 100. The seals 144 are configured as electrical feedthroughs that protect the electrical connections powering the heating elements 138.

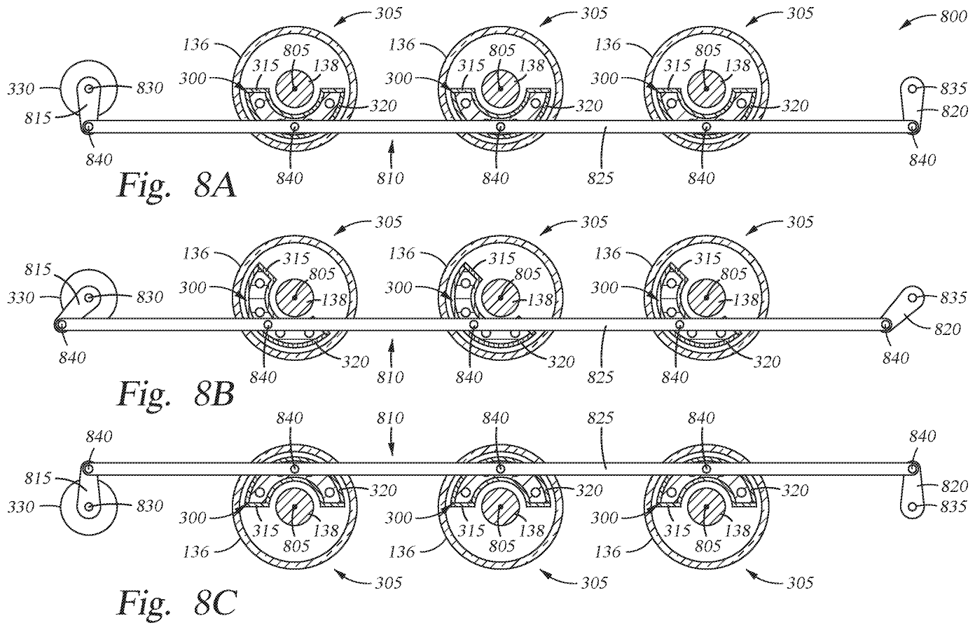

FIGS. 8A-8C are schematic side views of an actuator system 800 for rotating the internal reflectors 300 about a longitudinal axis 805 of each of the heating elements 138. The actuator system 800 includes the actuator 330 that is coupled to a linkage structure 810. The linkage structure 810 includes a first arm 815 and a second arm 820 that are coupled to each other by a central linking arm 825. The first arm 815 is coupled to the actuator 330 by a drive shaft 830. The second arm 820 is coupled to the chamber (not shown) by an idler shaft 835. The central linking arm 825 is coupled to each of the first arm 815, the second arm 820, and to each of the internal reflectors 300, by a pin 840. The actuator system 800 may be utilized with the first set of heating devices 132 and the second set of heating devices 134 as disclosed in FIGS. 3A-5. While not described in detail, the actuator system 800 as disclosed in FIGS. 8A-8C may be utilized with the shutters 610 described in FIG. 6.

Embodiments of the processing chambers as disclosed herein were tested and showed a reduction in thermal energy required to maintain a processing temperature of a substrate. The maintained processing temperature of the substrate during testing was about 1135 degrees Celsius. In some tests, a power reduction of 50% was observed. In other tests, a power reduction of about 60% was observed.

While the foregoing is directed to embodiments of the disclosure, other and further embodiments of the disclosure may be devised without departing from the basic scope thereof, and the scope thereof is determined by the claims that follow.

1. A chamber, comprising:
a body;
a susceptor positioned within the body;
a first set of heating devices positioned in an upper portion of the body above the susceptor; and
a second set of heating devices positioned in a lower portion of the body below the susceptor, wherein each of the first set of heating devices have a heating element having a longitudinal axis extending in a first direction, and each of the second set of heating devices have a heating element having a longitudinal axis extending in a second direction, and wherein each of the heating elements have ends that are exposed to ambient environment.

2. The chamber of claim 1, the first direction is orthogonal to second direction.

3. The chamber of claim 1, the first direction is parallel to second direction.

4. The chamber of claim 1, further comprising an inject manifold and an exhaust manifold that provides a flow path in the first direction across the susceptor.

5. The chamber of claim 4, wherein first direction is substantially orthogonal to the flow path.

6. The chamber of claim 4, wherein the first direction is generally parallel to the flow path.

7. The chamber of claim 1, further comprising:
a liner coupled to a top of the body; and
a liner coupled to a bottom of the body, wherein each of the liners comprise a thermal or optical isolation material and face the susceptor.

8. The chamber of claim 7, wherein each of the liners comprise an emissivity value of 0.7 or less.

9. The chamber of claim 1, wherein each of the heating elements are disposed in a tube comprising an optically transparent material.

10. The chamber of claim 9, wherein an interior of each of the tubes are in fluid communication with ambient environment.

11. A chamber, comprising:
a body;
a susceptor positioned within the body;
a first set of heating devices positioned in an upper portion of the body above the susceptor;
a second set of heating devices positioned in a lower portion of the body below the susceptor; and
a boundary plate positioned between the susceptor and the first set of heating devices, wherein each of the first set of heating devices have a heating element having a longitudinal axis extending in a first direction, and each of the second set of heating devices have a heating element having a longitudinal axis extending in a second direction, and wherein each of the heating elements are disposed in an optically transparent tube that extends outside of the body.

12. The chamber of claim 11, wherein the boundary plate comprises an optically transparent material.

13. The chamber of claim 11, wherein the boundary plate comprises an opaque material.

14. The chamber of claim 11, wherein each of the first set of heating devices and the second set of heating devices comprises a rotatable body.

15. The chamber of claim 14, wherein each of the rotatable bodies comprise a first side and a second side opposing the first side, wherein the second side is less reflective than the first side.

16. The chamber of claim 15, wherein the first side comprises a reflective coating or surface treatment having an emissivity of about 0.5 or less, and the second side comprises a reflective coating or surface treatment having an emissivity of greater than about 0.5.

17. The chamber of claim 14, wherein each of the rotatable bodies comprises an arc shaped member.

18. The chamber of claim 14, wherein each of the rotatable bodies comprises a rectangle shaped member.

19. The chamber of claim 11, further comprising a plurality of coolant channels formed in the body.

20. A chamber, comprising:
a body;
a susceptor positioned within the body;
a first set of heating devices positioned in an upper portion of the body above the susceptor;
a second set of heating devices positioned in a lower portion of the body below the susceptor;
a boundary plate positioned between the susceptor and the first set of heating devices, wherein each of the first set of heating devices have a heating element having a longitudinal axis extending in a first direction, and each of the second set of heating devices have a heating element having a longitudinal axis extending in a second direction, and wherein each of the heating elements are disposed in an optically transparent tube that extends outside of the body, and
a coolant source in fluid communication with a portion of the first set of heating devices and the second set of heating devices.
